(19) United States
(12) Patent Application Publication
(10) Pub. No.: US 2023/0262921 A1
(43) Pub. Date: Aug. 17, 2023

(54) FLOATING DATA COMMUNICATION MODULE

(71) Applicant: SAMTEC, INC., New Albany, IN (US)

(72) Inventor: Clarence L. CLYATT, III, New Albany, IN (US)

(21) Appl. No.: 18/005,500

(22) PCT Filed: Jul. 14, 2021
(86) PCT No.: PCT/US2021/041594

§ 371 Date: Jan. 13, 2023

Related U.S. Application Data
(60) Provisional application No. 63/051,860, filed on Jul. 14, 2020.

(51) Int. Cl. H05K 7/14

(52) U.S. Cl. CPC H05K 7/1491

(57) ABSTRACT

A data communication system includes a rack and one or more modules pluggable into the rack along a longitudinal direction. The rack can include one or more of an electrical connector, an RF cable connector, and an optical connector. One or both of the RF cable connector and the optical connector can float in one or more directions perpendicular to the longitudinal direction to align with respective connectors of the rack when the modules plug into the rack.

### CROSS-REFERENCE TO RELATED APPLICATIONS

This claims priority to U.S. Patent Application Ser. No. 63/051,860 filed Jul. 14, 2020, the disclosure of which is incorporated by reference as if set forth in its entirety herein.

### BACKGROUND

Conventional data communication assemblies include one or more communication modules that each include one or more electrical connector and/or optical connector disposed. The modules are pluggable into a rack that also include one or more complementary electrical connector and/or optical connector mounted on a backplane. When the modules are plugged into the rack, the connectors mate to place the connectors in communication with each other, thereby establishing electrical and/or optical data communication. The communication modules and the rack typically include alignment members that engage to ensure that the communication modules are correctly positioned and oriented to mate with the rack.

However, even when the alignment members correctly engage, tolerance and other factors can cause the connectors of the communication modules and the rack to be slightly out of alignment. When this occurs, attempting to jam the communication modules into the racks when the connectors are not adequately aligned can create excessive normal forces when the connectors are mated, thereby increasing the difficulty of removing the modules from the rack when desired. In more extreme examples, one or more of the connectors can become damaged. What is therefore needed is a data communication system that improves alignment between the connectors of a communication module and the connectors of a rack.

### SUMMARY

In one example, an RF connector assembly can include a frame that defines an aperture, wherein the aperture extends through the frame along a longitudinal direction. The RF connector assembly can further include a module housing sized to be received in the aperture, wherein the module housing supports at least one electrical cable connector. The RF connector assembly can further include a retention member configured to attach to the module housing, such that the module housing floats with respect to the frame.

### BRIEF DESCRIPTION OF DRAWINGS

The following detailed description will be better understood when read in conjunction with the appended drawings, in which there is shown in the drawings example embodiments for the purposes of illustration. It should be understood, however, that the present disclosure is not limited to the precise arrangements and instrumentalities shown. In the drawings:

FIG. 1 is a perspective view of a data communication assembly including a rack and a plurality of communication modules inserted into the rack;

FIG. 2A is an elevation view of the communication module of FIG. 1, shown including a data communication system constructed in accordance with one example;

FIG. 2B is a perspective view of the communication module of FIG. 2A;

FIG. 2C is a side elevation view of the communication module of FIG. 2A

FIG. 3 is a perspective view of a module substrate of the communication module of FIG. 2A, and a data communication system shown mounted to the module substrate, wherein the data communication system is shown including an electrical connector;

FIG. 4A is a rear perspective of a view of the module of FIG. 3, but showing the data communication system as further including an RF connector assembly and an optical assembly, and shown aligned to be mated with a backplane in the rack, wherein the rack includes a complementary electrical connector, a complementary RF connector assembly, and a complementary optical connector all mounted to the backplane;

FIG. 4B is an elevation view of the communication module of FIG. 4A;

FIG. 4C is an elevation view of the communication module of FIG. 4B, but shown the RF connector assembly constructed in another example;

FIG. 5A is an elevation view of a data communication system of the communication module shown mounted to a substrate in one example, wherein the data communication system includes an electrical connector and an optical assembly including a plurality of optical connectors;

FIG. 5B is a perspective view of the data communication system of FIG. 5A shown mounted to the substrate;

FIG. 5C is a perspective view of a backplane of the rack illustrated in FIG. 1 in accordance with one example, and a plurality of complementary communication devices including a complementary electrical connector and a complementary optical connector shown mounted to the backplane and configured to mate with the data communication system of FIG. 5A;

FIG. 5D is an elevation view of a data communication system of the communication module of FIG. 5A, but showing the optical assembly including a different number of optical connectors in another example;

FIG. 6A is a perspective view of a communication module including an RF cable connector assembly, and configured to receive an optical connector assembly;

FIG. 6B is a perspective view of a backplane of a rack, including a complementary RF cable connector assembly configured to mate with the RF cable connector assembly of FIG. 6A;

FIG. 7A is an exploded perspective view of a portion of the RF cable connector assembly;

FIG. 7B is a sectional side elevation view of the portion of the RF cable connector assembly illustrated in FIG. 7A;

FIG. 7C is a sectional side elevation view of a data communication system including an electrical RF cable mounted to the RF cable connector assembly of FIG. 7B;

FIG. 8A is an elevation view of a retention member of the RF cable connector assembly of FIG. 7A;

FIG. 8B is an elevation view of a support housing of the RF cable connector assembly of FIG. 7A;

FIG. 8C is an elevation view of a module housing of the RF cable connector assembly of FIG. 7A;

FIG. 8D is a sectional side elevation view of the module housing of FIG. 8C, taken along section line A-A;

FIG. 8E is a sectional side elevation view of the module housing of FIG. 8C, taken along section line B-B;

FIG. 8F is an elevation view of an alignment housing of the RF cable connector assembly of FIG. 7A;

FIG. 9A is a side elevation view of a cable connector configured to be supported by the module housing of FIG. 8C;

FIG. 9B is a sectional side elevation view of a portion of the RF cable connector assembly, showing the cable connector of FIG. 9A inserted in the module housing of FIG. 8C;

FIG. 10A is a top plan view of a portion of a data communication system, including an electrical cable connector and an optical cable connector;

FIG. 10B is a sectional plan view of an enlarged portion of the data communication system of FIG. 10A;

FIG. 11A is a perspective view of a portion of the optical assembly of the rack as shown in FIG. 5B;

FIG. 11B is a perspective view of an optical housing of an optical connector of the optical assembly shown in FIG. 11A;

FIG. 11C is another perspective view of the optical housing of FIG. 11B; and

FIG. 11D is a perspective view of the optical connector of FIG. 11A.

### DETAILED DESCRIPTION

As used herein, the singular forms “a,” “an,” and “the” include “at least one” and a plurality. Further, reference to a plurality as used in the specification including the appended claims includes the singular “a,” “an,” “one,” and “the,” and further includes “at least one.” Further still, reference to a particular numerical value in the specification including the appended claims includes at least that particular value, unless the context clearly dictates otherwise.

The term “plurality”, as used herein, means more than one. When a range of values is expressed, another example includes from the one particular value and/or to the other particular value. Similarly, when values are expressed as approximations, by use of the antecedent “about,” it will be understood that the particular value forms another example. All ranges are inclusive and combinable.

The term “substantially,” “approximately,” and derivatives thereof, and words of similar import, when used to described sizes, shapes, spatial relationships, distances, directions, and other similar parameters includes the stated parameter in addition to a range up to 10% more and up to 10% less than the stated parameter, including up to 5% more and up to 5% less, including up to 3% more and up to 3% less, including up to 1% more and up to 1% less.

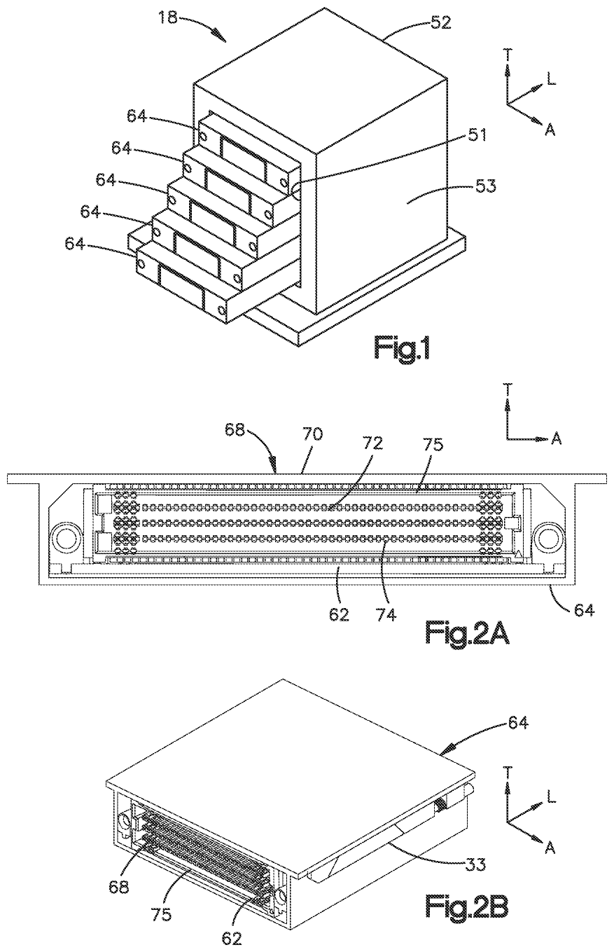

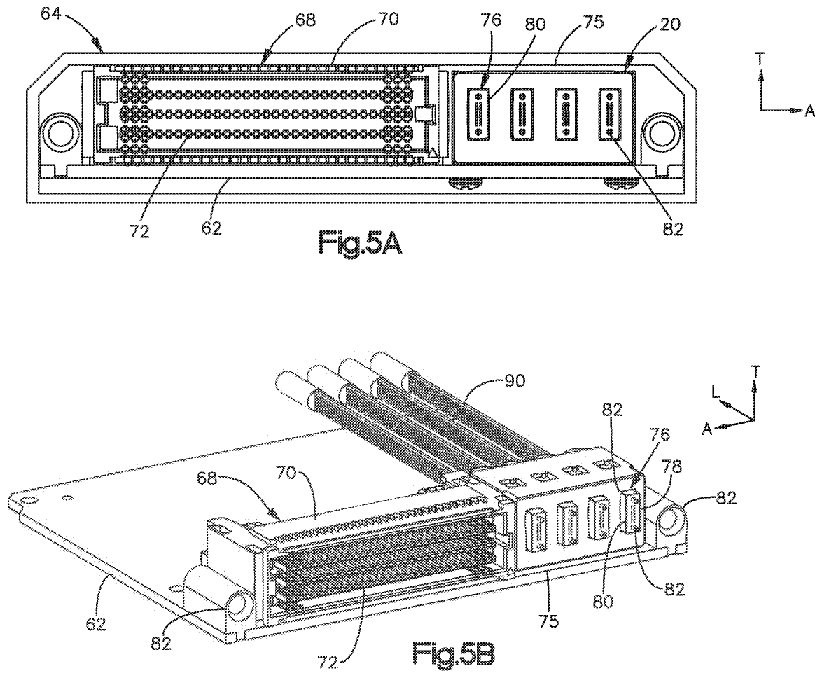

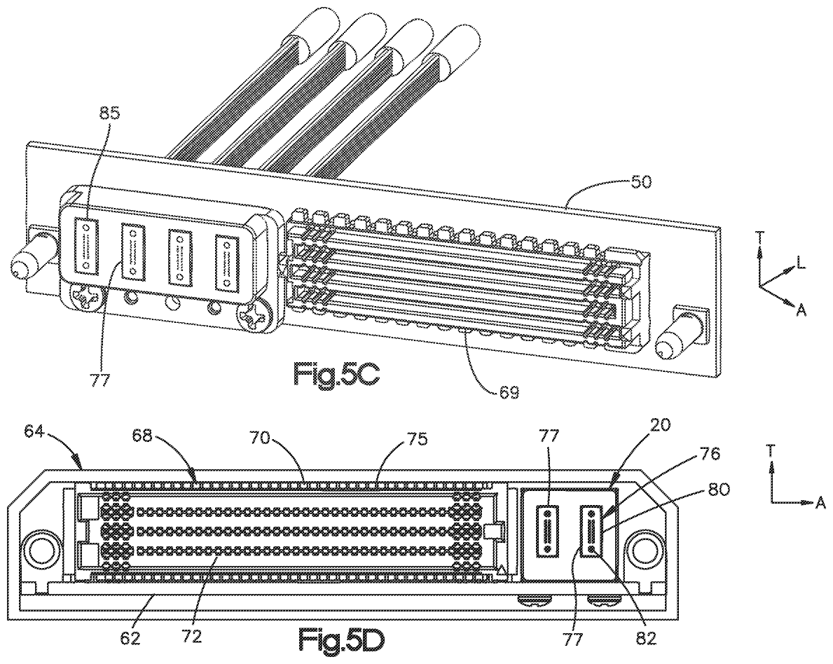

Referring to FIGS. 1-3, a data communication assembly 18 includes a rack 52 and a plurality of communication modules 64 that are pluggable into the rack 52. In particular, the communication modules 64 can be configured to be inserted into the rack so as to place the communication modules 64 in data communication with complementary communication devices of the rack 52. In particular, as will be described in more detail below, the rack 52 includes a rack housing 53 and a backplane 50 (see FIG. 5C) disposed in the rack housing 53. The rack housing 53 defines a receptacle 19 that is configured to slidably receive the communication modules 64 along an insertion or mating direction that can be oriented along a longitudinal direction L. In particular, the rack housing 53 can define a plurality of channels 51 that are configured to receive respective communication modules 64. The channels 51 can be arranged in pairs that are opposite each other along a lateral direction A that is oriented perpendicular to the longitudinal direction L. The channels 51 can further be elongate along a longitudinal direction L. Respective pairs of the channels 51 can be open at the receptacle 19 and configured to receive respective ones of the communication modules 64.

The communication module 64 can include a module housing 30 and a module substrate 62 that is supported by the module housing 30. For instance, the module substrate 62 can be supported in the module housing 30. In some examples, the module substrate 62 can be configured as a printed circuit board. Further, the module substrate 62 can be oriented along the lateral direction A and the longitudinal direction L. The module housing 30 can define a housing body 31 that, in turn, at least partially defines an enclosure that contains the module substrate 62. The module housing 30 can further defines a pair of rails 33 that extend out from the housing body 31 along the lateral direction A. The rails 33 are sized and configured to be slidably received in a respective one of the pairs of channels 51 so as to insert the communication module 64 into the rack 52 in the forward insertion direction. When it is desired to remove the communication module 64 from the rack 52, the communication module 64 can be translated along a removal direction that is opposite the insertion direction and also oriented along the longitudinal direction L. The insertion direction can be referred to as a forward direction, and the removal direction can be referred to as a rearward direction. The modules 64 can be stacked on each other along a transverse direction T that is oriented perpendicular to the longitudinal direction L and the lateral direction A. The modules 64 can be sized as desired along the longitudinal direction L, the transverse direction T, and the lateral direction A as desired. For instance, the modules 64 can be sized substantially equally or differently as desired.

With continuing reference to FIGS. 1-3, the communication module 64 can include a data communication system 20 that, in turn, includes one or more communication devices at a mating interface 75 of the communication module 64. The one or more communication devices can be mounted to or otherwise supported by the module substrate 62. The communication module 64 can be inserted into the rack 52 in the manner described above until the communication module 64 mates with the rack 52. When the communication module 64 is mated with the rack, the one or more communication devices of the data communication system 20 mate with a respective one or more complementary communication devices of the rack along the mating direction. When a communication device of the communication module 64 is mated with a complementary communication device of the rack 52, the communication devices are placed in communication with each other with respect to the transfer of data. Thus, data signals can flow from the communication module 64 to the rack 52, and/or from the rack 52 to the communication module 64 as desired. As will be appreciated from the description below, the data signals can be configured as electrical signals, optical signals, or a combination of electrical and optical signals.

In one example, the data communication system 20 of the communication module 64 can include an electrical connector 68 that includes a dielectric or electrically insulative connector housing 70 and a plurality of electrical contacts 72 supported by the connector housing 70. The electrical contacts 72 can define respective mounting ends that are mounted to the module substrate 62, and mating ends 74 that are disposed at the mating interface 75. The mating ends 74 are configured to mate with electrical contacts of a complementary electrical connector 69 (see FIG. 5C) of the rack 52 when the module 64 is inserted into the rack 52. Thus, the electrical contacts 72 are configured to place the module substrate 62 in electrical communication with the complementary electrical connector 69 of the rack 52. The electrical connector 68 can be a SEARAY electrical connector commercially available from Samtec, Inc having a principal place of business in New Albany, Ind., though it is appreciated that the electrical connector 68 can be configured as any suitable electrical as desired. Further, the electrical connector 68 can be a right-angle electrical connector in some examples, whereby the mating ends 74 are oriented perpendicular with respect to the mating ends 74.

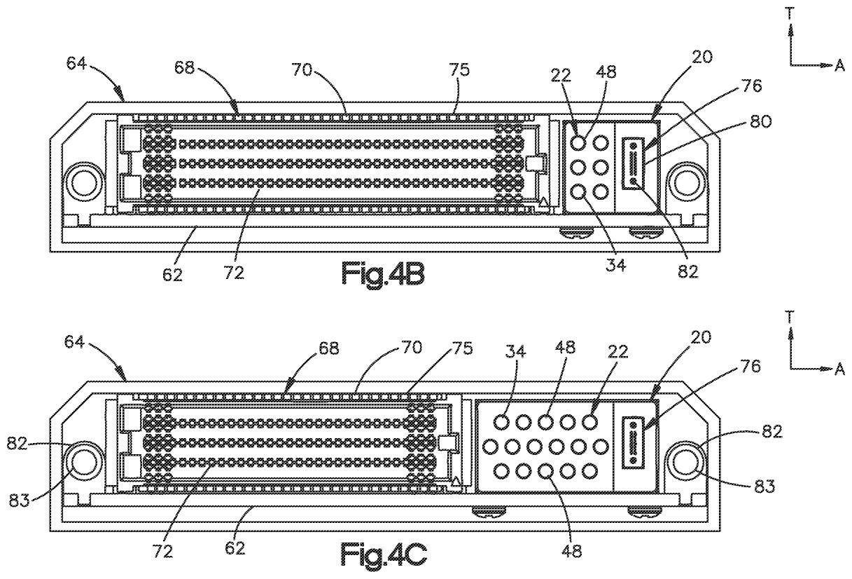

As illustrated in FIGS. 4A-6B, the one or more communication devices of the data communication system 20 of the communication module 64 can include one or more radio frequency (RF) cable connectors 34 of an RF connector assembly 22. The cable connectors 34 can be mounted directly to the module substrate 62 or otherwise supported by intermediate structure that, in turn, is supported by the module substrate 62. The cable connectors 34 can each define respective mating ends 48 configured to mate with complementary cable connectors 55 of a complementary RF connector assembly 57 of the rack 52, to provide further data communication between the rack 52 and the communication module 64. The mating ends 48 of the cable connectors 34 can be disposed adjacent the mating ends 74 of the electrical contacts 72 of the electrical connector 68. A plurality of transmission lines can be mounted to respective mounting ends of ones of the electrical cable connector 34, such that the mating ends 48 of the electrical cable connectors 34 are spaced from the transmission lines in the forward direction. The transmission lines can be configured as electrical cables in one example. The electrical cables can extend to another connector in one example. Alternatively, the transmission lines can terminate at the substrate 62 in a right-angle configuration. When the transmission lines are configured as electrical cables, the electrical cables 58 can be configured as coaxial electrical cables, twinaxial electrical cables, or any alternatively configured cables as desired. When the transmission lines define an alternative configuration from an electrical cable, the RF cable connectors 34 can be referred to as RF connectors.

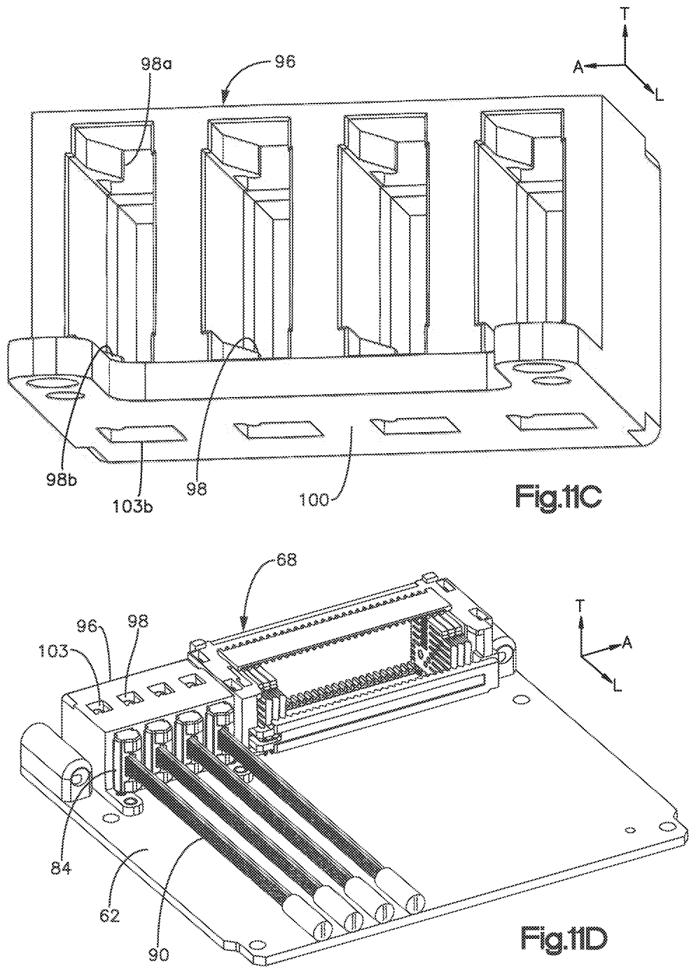

Further, the one or more communication devices of the data communication system 20 of the communication module 64 can further include an optical assembly 76 that includes one or more optical connectors 78 configured to mate with a complementary one or more optical connectors 77 of the rack 52. The optical connectors 77 can be mounted to one or more optical transmission lines that can extend to another optical connector in one example. Alternatively, the transmission lines can terminate at the substrate 62 in a right-angle configuration. The transmission lines can be configured as optical cables 90 in certain examples. The optical connectors 78 of the communication modules 64 can mate with the complementary optical connectors 77 of the rack 52 to provide optical data communication between the rack 52 and the communication module 64 (see FIG. 11A). The optical assembly 76 can be mounted directly to the module substrate 62 or otherwise supported by intermediate structure that, in turn, is supported by the module substrate 62.

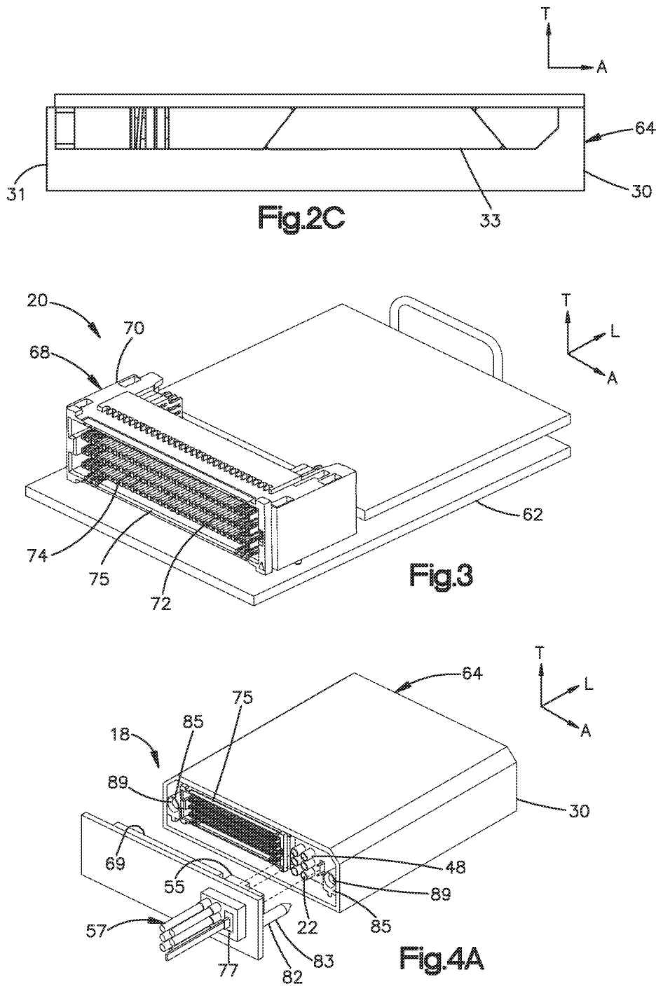

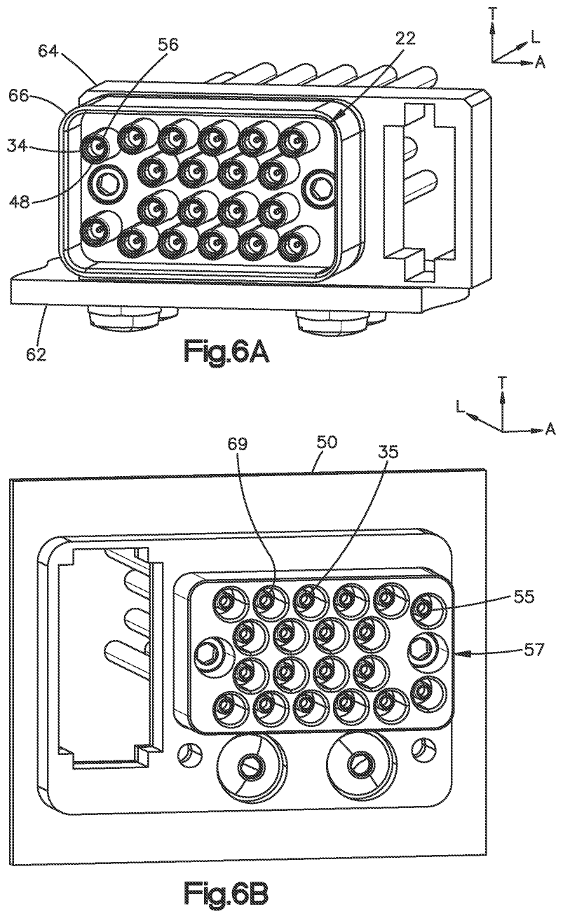

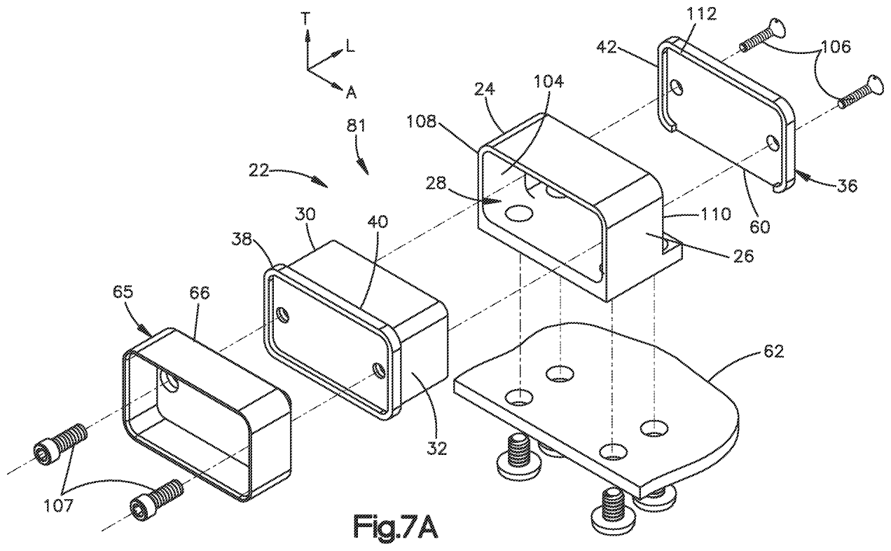

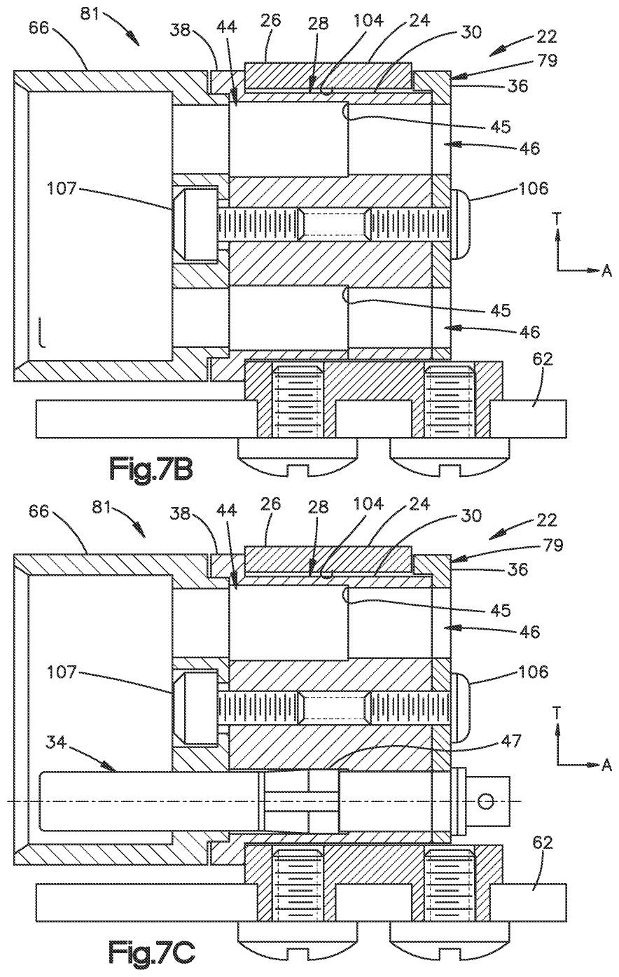

The electrical connector 68, the RF connector assembly 22, and the optical assembly 76 can be arranged as desired along the mating interface 75 of the communication module 64. For instance, the RF connector assembly 22 can be disposed between the electrical connector 68 and the optical assembly 76 with respect to the lateral direction A. Further, it should be appreciated that the communication module 64 can include any one or more up to all of the electrical connector 68, the RF connector assembly 22, and the optical assembly 76. In one example, the communication module 64 can include the electrical connector 68 alone or in combination with either or both of the RF connector assembly 22 and the optical assembly 76. For instance, FIGS. 2A-3 show the communication module 64 as including the electrical connector 68 without the RF connector assembly 22, and without the optical assembly 76. FIGS. 4A-4C show the communication module 64 as including each of the electrical connector 68 without the RF connector assembly 22, and without the optical assembly 76. FIG. 5A-5B show the communication module 64 as including the electrical connector 68 and the optical assembly 76, but without the RF connector assembly 22. FIG. 6A shows an example whereby the communication module 64 includes the RF connector assembly and the optical assembly 76. While the optical connector 78 is not shown in FIG. 6A, the communication module 64 is shown having a common housing 87 that supports an RF connector 78 and defines an opening 41 that receives an optical connector 78 as shown in FIG. 4A. The common housing 87 can surround a support housing 24 (described below with respect to FIG. 7A) or can define the support housing 24 in some examples. Thus, the RF connectors 34 can float in the manner described below while the optical connectors 78 remain positionally fixed. Alternatively, the optical connectors 78 can float in the manner described below while RF connectors 78 remain positionally fixed.

The electrical connector 68, the RF connector assembly 22, and the optical assembly 76 can be sized and configured as desired. For instance, the electrical connector 68 can include any number of electrical contacts 68 that can be arranged along any number of rows and columns, whereby the rows are oriented along the lateral direction A and the columns are oriented along the transverse direction T. As one example, the electrical connector 68 illustrated in FIG. 4B has more columns than illustrated in FIG. 4C. Similarly, the RF connector assembly 22 can include any number of RF cable connectors 34 as desired. For instance, the RF connector assembly 22 can have any number RF cable connectors 34 that can be arranged along rows and columns, whereby the rows are oriented along the lateral direction A and the columns are oriented along the transverse direction T. As one example, the RF connector assembly 22 illustrated in FIG. 4C has more columns than illustrated in FIG. 4B. Further, the columns of RF cable connectors 34 can be aligned with each other as illustrated in FIG. 4B or staggered as illustrated in FIG. 4C. Similarly still, optical assembly 76 can include any number of optical connectors 78 as desired. The optical connectors 78 can be disposed adjacent each other along the lateral direction A. As one example, the optical assembly 76 illustrated in FIG. 5B has more columns than illustrated in FIG. 4B.

With continuing reference to FIGS. 4A-5D, and as described above, the rack 52 can include a backplane 50 and a plurality of complementary communication devices mounted to or otherwise supported by the backplane 50. The backplane 50 can be oriented along the transverse direction T and the lateral direction A. The rack 52 can include one or more complementary electrical connectors 69 mounted to the backplane 50 and configured to mate with the respective electrical connector 68 of one or more communication modules 64, thereby placing the backplane 50 and the substrate 62 in electrical communication with each other. The rack 52 can further include a complementary RF connector assembly 57 that includes a plurality of complementary cable connectors 55 mounted on the backplane 50. The complementary cable connectors 55 and the cable connectors 34 of the communication modules 64 are mounted to respective electrical cables that are placed in electrical communication with each other when the cable connectors 34 and 55 are mated with each other. Further still, the rack 52 can include one or more complementary optical connectors 77 that are mounted to the backplane 50. The complementary optical connectors 77 of the rack 52 and the optical connectors 78 of the communication modules 64 are mounted to respective optical cables 90 that are placed in optical communication with each other when the complementary optical connectors 77 and the optical connectors 78 are mated with each other.

It should be appreciated that the complementary communication devices of a single backplane 50 can mate with all of the communication modules 64, or that at least some of the communication modules 64 can mate with complementary communication devices of different backplanes 50 in the rack 52. Further, the communication modules 64 can include alignment members 82 that can be configured as pins 83 that are configured be received in respective complementary alignment members 85 of the rack 52 that can be configured as sockets 89 so as to align the communication devices of the communication modules 64 with the complementary communication devices of the rack 52 for mating as the communication modules 64 are plugged into the rack 52. The pins 83 can extend forward any one or more of the electrical connector 68, the RF cable connector assembly 22, and the optical assembly 76. Thus, the alignment apertures can extend into any one or more of the complementary electrical connector 69, the complementary RF connector assembly 57, and the complementary optical connector 77. It will be appreciated that the alignment members 82 of the communication modules 64 can alternatively be configured as sockets, and the alignment members 85 of the rack 52 can alternatively be configured as pins that are received in the sockets. Further, as will be appreciated from the description below, one or more of the communication devices of the communication module 64 can be compliant in either or both of the lateral direction A and the transverse direction T so as to facilitate mating with the complementary communication devices.

It should be appreciated that the complementary communication devices of the rack 52 can include any one or more up to all of the complementary electrical connector 69, the complementary RF connector assembly 57, and the complementary optical connectors 77 mounted to the backplane 50. In one example shown in FIG. 4A, the complementary communication devices of the rack 52 are shown as including the complementary electrical connector 69 and the complementary optical connectors 77 mounted to the backplane 50, but not the complementary RF connector assembly 57. In other examples, the complementary communication devices of the rack 52 can include including the complementary electrical connector 69 the complementary RF connector assembly 57 mounted to the backplane, but not and the complementary optical connectors 77.

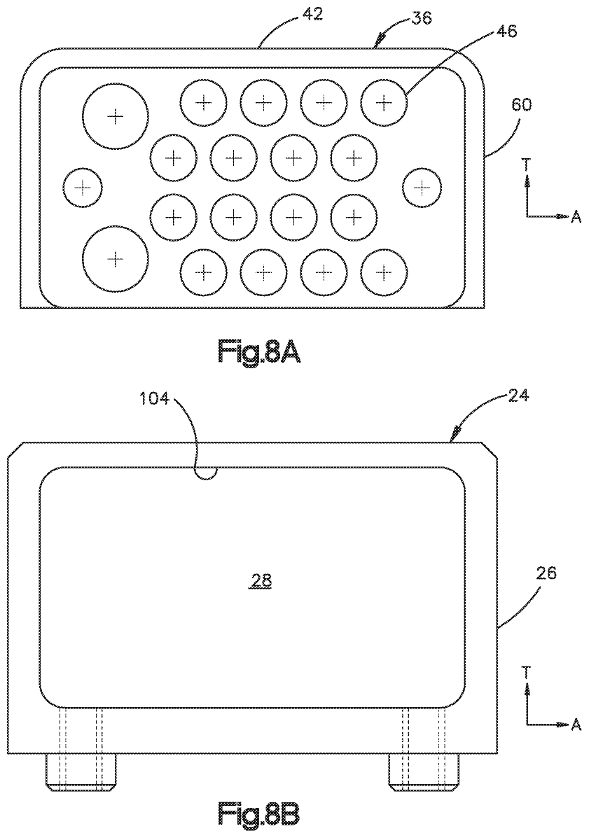

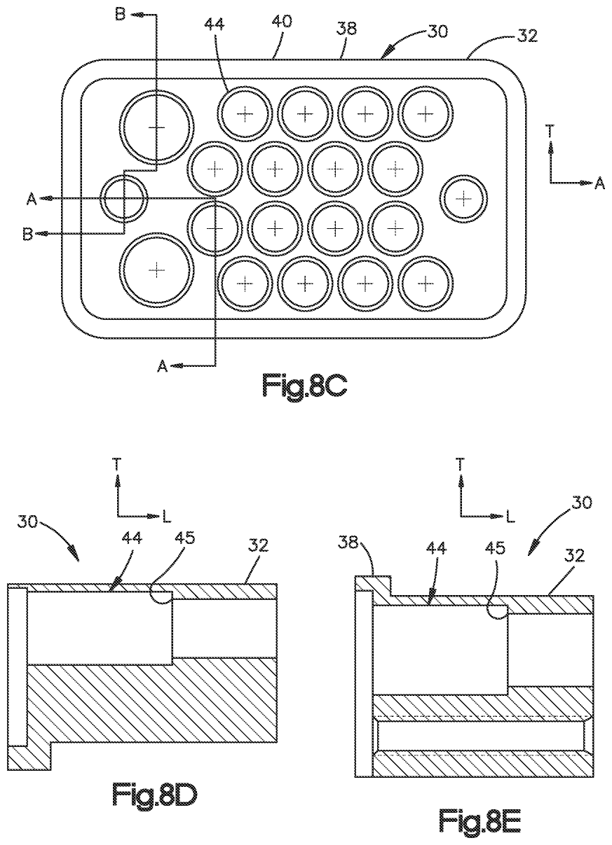

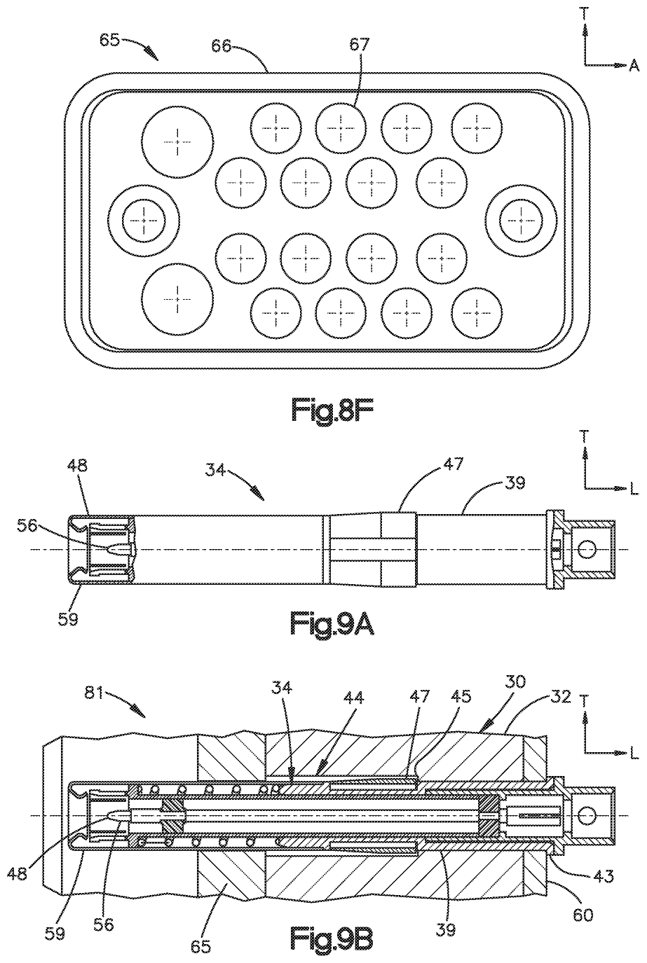

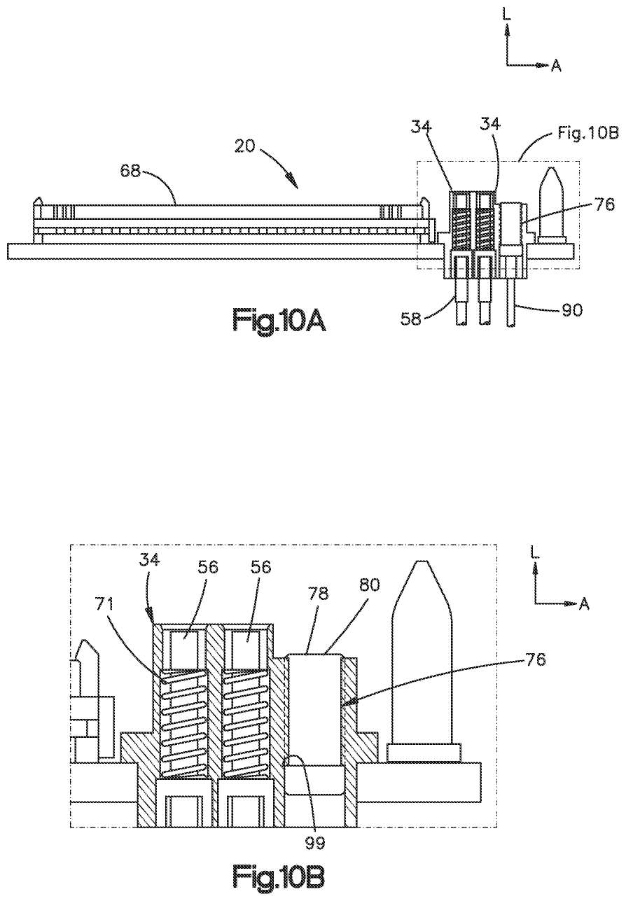

Referring now to FIGS. 6A-9B, the RF cable connectors 34 can be configured to float with respect to the underlying substrate 62. That is, the cable connectors 34 can be configured to translate in any direction that is perpendicular to the longitudinal direction L. In one example, the cable connectors can undergo translation without angulation. Thus, an orientation of the cable connectors 34 can remain constant before, during, and after translation. Because the respective RF cable connector housings 39 of the RF cable connectors 34 not spring-biased along the longitudinal direction L, they can be referred to as free floating with respect to motion along a direction perpendicular to the longitudinal direction. The optical connectors 78 can similarly be configured to float with respect to the underlying substrate 62 as described herein with respect to the RF cable connectors 34.

During operation, when the rack 52 and communication module 64 mate with each other, the alignment members 82 of the communication modules 64 engage the complementary alignment apertures 85 of the rack 52. It is recognized that when the alignment members 82 and 85 are engaged, the possibility exists that the RF cable connectors 34 and the optical connectors 78 are not aligned for mating with the complementary RF cable connector 55 and the complementary optical connectors 77, respectively. The RF cable connectors 34 and the optical connectors 78 can thus be configured to float in a direction perpendicular to the longitudinal direction L so as to bring the connectors of the communication module 64 into alignment with the complementary connectors of the rack 52 for mating.

A floating connector support assembly 81 can include a module housing 30 that can retain one or more connectors such as the RF cable connectors 34, a support housing 24 that supports the module housing 30, a retention member 36 configured to attach to the module housing 30, and an alignment housing 65 configured to attach to the module housing 30. The module housing 30, the support housing 24 the retention member 36, and the alignment housing 65 can be made of any suitable material as desired, such as metal. The RF connector assembly 22 can include the floating connector support assembly 81 and one or more RF cable connectors 34 supported by the floating connector support assembly 81. The alignment housing 65 is configured to mate with the housing of the complementary RF connector 55 and provide alignment between the RF connector assembly 22 and the complementary RF connector assembly 57 (see FIG. 5C). The module housing 30 can be disposed adjacent the retention member 36 in the forward direction. The alignment housing 65 can extend from the module housing 30 in the forward direction. Further, the alignment housing 65 can be coupled to the module housing 30 by fasteners 107, such that the alignment housing 65 is rigidly fixed to the module housing 30. Similarly, the module housing 30 can be coupled to the retention member 36 by fasteners 106, such that the module housing 30 is rigidly fixed to the retention member 36. Thus, the module housing 30 and the retention member 36 can be separable. The fasteners 106 and 107 can be configured as externally threaded bolts and screws, snap members, latches, or any alternative fastener as desired. As a result, the retention member 36, the module housing 30, and the alignment housing 65 are fixed to each other and move with each other relative to the support housing 24. Because the support housing 24 can be mounted to the substrate 62, the retention member 36, the module housing 30, and the alignment housing 65 are fixed to each other and move with each other relative to the substrate 62.

The support housing 24 defines a frame 26 and an aperture 28 that extends through the frame 26 along the longitudinal direction L. Thus support housing 24, and thus the frame 26, can be a unitary monolithic structure. The support housing 23 can be mounted to the underlying substrate 62 using any suitable mechanical fastener. The module housing 30 defines a module body 32 sized to be received in the aperture 28. The retention member 36 can attach to the module housing 30 so as to capture the support housing 24 between the retention member 36 and the module housing 30 when the support housing 24 extends through the aperture 28. In some examples, the module housing 30 and the retention member 36 cannot be removed from the frame 26 until fasteners 106 are released and the retention member 36 or the module housing 30 are removed from the frame 26. The module housing 30 supports at least one RF cable connector 34 such as a plurality of RF cable connectors 34. The module body 32 can be sized smaller than the aperture 28 in a plane that is oriented perpendicular to the longitudinal direction L. For instance, the module body 32 can be sized smaller than the aperture 28 in at least one or both of the lateral direction A and the transverse direction T. Otherwise stated, the aperture 28 can be sized greater than at least a portion up to an entirety of the module body 32 in each of the lateral direction A and the transverse direction T. The aperture 28 can have a substantially constant size with respect to a plane along at least a majority up to an entirety of its longitudinal length through the support housing 24, wherein the plane is oriented perpendicular to the L longitudinal direction.

Thus, when the module housing 30 extends through the aperture 28, the module housing 30 is movable inside the aperture with respect to the support housing 24 and the underlying substrate 62 along a direction that is angularly offset with respect to the longitudinal direction L. For instance, the module housing 30 can be movable with respect to the support housing 24 and substrate 62 along at least one of the lateral direction A and the transverse direction T. Thus, the alignment housing 65 is also movable with respect to the support housing 24 and the substrate 62 so as to align with the complementary RF connector of the rack 52. In particular, the alignment housing 65 can define a shroud 66 that projects in the forward direction and is configured to receive a complementary device that supports the complementary electrical RF cable connector 35 of the rack 52. Because the module housing 30 retains the at least one RF cable connectors 34, movement of the module housing 30 with respect to the support housing 24 and substrate correspondingly moves the electrical cable connector 34 that is supported by the module housing 30. While FIGS. 6A-9B show RF cable connectors 34 9B, it should be appreciated that the electrical cables 58 can be replaced by any suitable alternative electrically conductive transmission line as described above, such as any suitable electrical conductor.

Referring now to FIGS. 7A-7C in particular, the module housing 30 defines a first stop member 40, and the retention member 36 defines a second stop member 42. The first and second stop members 40 and 42 can be aligned with the frame 26 along the longitudinal direction L. Thus, when the retention member 36 is secured to the module body 32, the frame 26 is disposed between the first and second stop members 40 and 42 with respect to the longitudinal direction L. The first stop member 40 can be disposed adjacent the frame 26 in the forward direction, and the second stop member 42 can be disposed adjacent the frame 26 in the rearward direction. Thus, the frame 26 is disposed between the first and second stop members 40 and 42. The distance between the first and second stop members 40 and 42 along the longitudinal direction L can be slightly greater than the longitudinal distance of the module housing 30, sufficiently greater in order to allow for translation of the module housing 30 along each of the lateral direction A and the transverse direction T with respect to the support housing 24 and the underlying substrate 62. The module housing 30 can undergo translation without angulation in certain examples. Thus, the first and stop members 40 and 42 can guide the module housing to translate in all directions along a plane that is oriented perpendicular to the longitudinal direction L with respect to the support housing 24 and underlying substrate 62 while maintaining its orientation. Alternatively, the distance between the first and second stop members 40 and 42 along the longitudinal direction L can be sufficiently greater than the longitudinal distance of the module housing 30 in order to allow for angulation of the module housing 30 with respect to the support housing 24 and the underlying substrate 62.

In one example, the first stop member 40 can be defined by a flange 38 that projects out from the module body 32 along at least one direction perpendicular to the longitudinal direction L. Thus, the module housing 30, including the module body 32 and the flange 38, is sized greater than the aperture 28 along the at least one direction so to abut a first or front surface 108 of the frame 26. In one example, the flange 38 can project out from at least two sides of the module body 32. The two sides can be opposite each other or adjacent each other. In a further example, the flange 38 can project out from all sides of the module body, such that the flange 38 extends along an entire perimeter of the module body 32 with respect to a plane oriented perpendicular to the longitudinal direction L. At least a portion up to an entirety of the module body 32 extends from the flange 38 in the rearward direction. Thus, the flange 38 can be prevented from physically contacting a second or rear surface 110 of the frame 26 that is spaced from the first surface in the rearward direction.

The second stop member 42 can be defined by the retention member 36. In particular, the retention member 36 can have a retention body 60 and a flange 112 that projects out from the retention body 60. The retention body 60 can be oriented substantially along a plane that is oriented perpendicular to the longitudinal direction L, and can define the second stop member 42. The flange 112 can extend from the retention body 60 in the forward direction so as to surround the frame 26. Alternatively, the flange 112 can define the second stop member 42 as desired. The retention member 36 can be configured to abut the second surface 110 of the support housing 24 but is prevented from physically contacting the first surface 108. When the retention member 36 is fixed to the module housing 30, a first length from the first stop member 40 to the second stop member 42 along the longitudinal direction L can be slightly greater than a total length of the frame 26 along the longitudinal direction L. Abutment between the support housing 24, in particular the frame 26, more particularly an interior surface of the frame 26 that defines the aperture 28, and an outer surface of the module body 32 can limit movement of the module body 32 with respect to either or both of the support housing 24 and the substrate 62 in each of the lateral direction A and the transverse directions T. The support housing can be completely devoid of recesses and grooves that extend into the interior surface. Thus in one example, neither the module housing 30 nor the retention member 36 sits in a recess or groove of the frame 26.

Referring now to FIGS. 7A-9B, and as described above, the retention member 36, the module housing 30, and the alignment housing 65 can all be configured to support the RF cable connectors 34. In particular, the module housing 30 defines at least one module housing channel 44 such as a plurality of module housing channels 44 that extend through the module body 32 along the longitudinal direction L. The module housing channels 44 are configured to receive the electrical cable connector 34. Similarly, the retention member 36 can define a plurality of retention member channels 46 that extend through the retention body 60. The channels 46 can be in alignment with the channels 44 of the module housing 30 along the longitudinal direction L. Similarly still, the alignment housing 65 can define a plurality of channels 67 that extend therethrough along the longitudinal direction L. The channels 67 can be in alignment with the channels 46 of the retention member 36 and the channels 44 of the module housing 30 along the longitudinal direction L. Thus, the RF cable connectors 34 extends through respective aligned ones of the retention member channels 46, the module housing channels 44, and the channels 67 of the alignment housing 65. The mating ends of the RF cable connectors 34 can extend through the channels 67 of the alignment housing 65 and into a void that is defined by the shroud 66. In one example, the mating ends 48 of the RF cable connectors 34 do not extend past the shroud 66 in the forward direction.

The RF cable connectors 34 can be retained in any suitable manner as desired. For instance, in one example, the module housing channel 44 can be stepped so as to define a shoulder 45. The RF cable connector 34 defines an RF cable connector housing 39 that includes one or more outwardly projecting spring fingers 47. The spring fingers 47 can be resiliently flexible. As the electrical cable connector 34 is inserted into the module housing channel 44 in the forward direction, the spring fingers 47 flex inwardly from an initial position as they ride along an internal surface of the module housing 30 that defines the channel 44, and thus also defines the shoulder 45. Because the spring fingers 47 are resilient, they are biased to move outward toward the initial position. Thus, as when they travel past the shoulder 45 as the RF cable connector 34 travels in the forward direction through the module housing channel 44, the spring fingers 47 flex outward to a position aligned with the shoulder 45 along the longitudinal direction L. Thus, abutment between the spring fingers 47 and the shoulder 45 prevents backout of the RF cable connector 34 along the rearward direction. It can therefore be said that the RF cable connectors 34 can be snap-fit in the module housing 30. The RF cable connector housing 39 can further include a rear abutment member 43 that can abut a rearward facing surface of the retention member 36. Thus, abutment between the abutment member 43 and the retention member 36 prevents movement of the RF cable connector 34 in the forward direction. During use, the RF cable connector 34 can be inserted into the module housing channel 44 until the abutment member 43 abuts the retention member 36, at which point the spring fingers 47 have traveled past the shoulder 45 in the manner described above. Accordingly, abutment of the spring fingers 47 and the shoulder 45, and abutment of the abutment member 43 and the retention member 36 prevent movement of the RF cable connector 34 along the longitudinal direction L with respect to a contact retention assembly 79 that can be defined by the module housing 30 and the retention member 36. In other examples, the abutment member 43 of the RF cable connector 34 can abut a rear facing surface of the module housing 30 to prevent movement of the RF cable connector 34 along the longitudinal direction L. It should therefore be appreciated that movement of the module housing 30 causes corresponding movement of the RF cable connector 34, the alignment housing 65, and the retention member 36, which are all fixed together with respect to relative movement with respect to each other in all directions perpendicular to the longitudinal direction L.

When it is desired to remove the RF cable connector 34 from the floating connector support assembly 81, the alignment housing 65 can be removed from the module housing 30. In particular, the fasteners can be removed, and the alignment housing can then be removed, which exposes the spring fingers 47. Thus, a removal instrument can be inserted rearward to deflect the spring fingers 47 inward and out of alignment with the shoulder 45, thereby removing the abutment that prevents backout of the RF cable connector 34 in the rearward direction. A rearward force can then be applied to the RF cable connector 34 with respect to the module housing 30 that causes the RF cable connector to be removed. While the shoulder 45 can be defined by the module housing 30 as described above, the shoulder 45 can alternatively be defined by alignment housing 65 or the retention member 36 as desired. Further, while the RF cable contact 34 is configured to be inserted in the forward direction and removed in the rearward direction, it should be appreciated that the RF cable contact 34 can alternatively be configured to be inserted in the rearward direction and removed in the forward direction.

The RF cable connector 34 can define a mounting end 49 that is configured to be secured to the electrical conductor of either the electrical cable 58 or alternatively configured transmission line, thereby placing the electrical cable 58 or alternatively configured transmission line in electrical communication with the mating end 48 of the RF cable connector 34. The RF cable connector can define a pin 56 at the mating end 48 that is configured to mate with an electrical contact of the complementary RF cable connector 55 of the rack 52, thereby placing the complementary RF cable connector 55 and backplane 50 in electrical communication with the electrical cable or alternatively configured transmission line. When configured as a transmission line that terminates at the substrate 62, the substrate 62 can be placed in electrical communication with the complementary RF cable connector 55 and backplane 50.

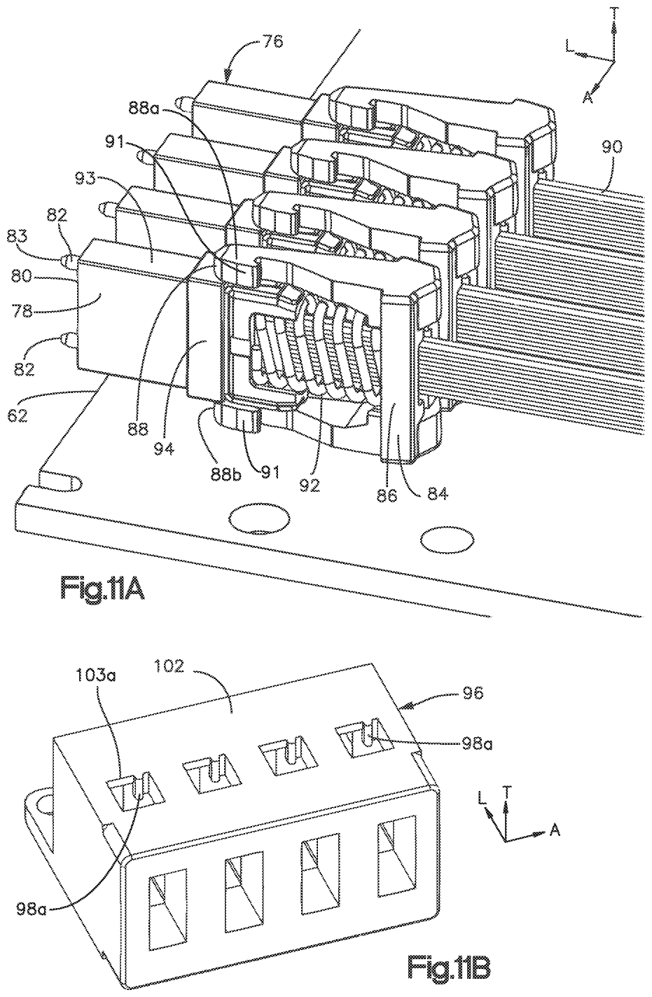

Referring also to FIGS. 10A-10B, the pin 56 can be surrounded by a sleeve 59 in an initial position. The sleeve 59 can be displaced from the initial position in the rearward direction so as to expose the pin 56 that then extends in the forward direction with respect to the sleeve 59. During use, the sleeve 59 can be displaced in the rearward direction as the RF cable connector 34 mates with the complementary RF cable connector 55 of the rack 52. The RF cable connector 34 can include a spring member 61 that applies a spring force to the pin 56 that biases the pin in the forward direction. Thus, the pin 56 can be movable in the rearward direction against the spring force.

While the floating connector support assembly 81 can support one or more RF cable connectors 34 in respective one or more channels 44 as described above, it should be appreciated that the one or more of the channels 44 can alternatively or additionally support a respective one or more of the optical connectors 78 in the manner described above with respect to the RF cable connectors 34. Thus, it should be appreciated that at least some up to all of the channels 44 retains corresponding electrical cable connector 34 that extend through the module housing 30. Alternatively or additionally, at least some up to all of the channels 44 retains corresponding optical connectors 78 that extend through the module housing 30. Accordingly, one or more RF cable connectors 34 and one or more optical connectors 78 can be supported by a common floating connector support assembly 81 in the manner described above with respect to the RF cable connectors 34. As a result, a common housing can support at least one optical connector 78 and at least one RF cable connector 34 that each includes a dielectric housing and transmission lines supported by the dielectric housings. The at least one optical connector 78 and at least one RF cable connector 34 can therefore float in the manner described with respect to the RF cable connector 34. In particular, the common housing that supports or otherwise contains the at least one optical connector 78 and at least one RF cable connector 34 can float in the manner described above. In this regard, the common housing can be defined by the module housing 30. Thus, the RF cable connector and the optical connector 78 can both float with respect to a common support housing 24 and underlying substrate 62. It should be appreciated that because the RF cable connector and the optical connector 78 can extend through the module housing 30, and the module housing 30 extends through the support housing 24, it can be said that the RF cable connector and the optical connector 78 extend through the common support housing 24. Otherwise stated, the common support housing 24 can contain each of the RF cable connector 34 and the optical connector 78. The channels 44 can have substantially the same diameter configured to receive connectors of substantially equal size. Alternatively, some of the channels 44 can have different diameters than at least one other one of the channels 44, such that the channels 44 are configured to receive connectors of different sizes. It is appreciated that the RF cable connectors 34 and the optical connectors 78 can be dimensioned substantially identically in a plane that is oriented perpendicular to the longitudinal direction L at a location where they extend through the channels 44, or can be dimensioned differently.

Referring now to FIGS. 11A-11D, the optical cable assembly 76, and thus the data communication system 20, can be supported by the substrate, and can include the optical connector 78, a support member 84, a plurality of optical cables 90 or alternative optical transmission lines, and a biasing member 92. The optical connector 78 defines a mating end 80 that is configured to mate with the complementary optical connector 77 of the rack 52. The mating end 80 of the optical connector 78 can be disposed adjacent the mating end 48 of at least one of the electrical cable connectors 34, meaning that no other connectors are disposed between the mating ends 80 and 48.

The optical connector 78 supports at least one alignment member 82 that extends out from the optical connector 78 in the forward direction. The support member 84 can have a support body 86 and at least one latch member 88 that extends from the support body 86 in the forward direction. The optical cables 90 can extend through the support member 84 and terminate at the optical connector 78, such that the optical cables 90 are in optical communication with the mating end 80. The biasing member 92 can extend from the optical connector 78 to the support member 84 so as to bias the optical connector 78 in the forward direction. The biasing member 92 can allow for resilient movement of the optical connector 78 with respect to the support member 84 along a direction offset from a longitudinal direction L that includes the forward direction and a rearward direction opposite the forward direction. The optical assembly 76 can include an optical housing 96 configured to receive the optical cables 90. In particular, the optical cables 90 can pass through the biasing member 92 and through an optical housing 96 in the forward direction, and into the optical connector 78. The latch member 88 can be cantilevered from the support body 86.

In one example, the optical connector 78 can support first and second alignment members 82 that are spaced from each other along the transverse direction T. The latch member 88 can a hook or barb 91 in a plane that includes the longitudinal direction L and the lateral direction A. The optical connector 78 can further include an alignment support housing 94, such that the alignment members 82 are secured in the alignment support housing 94. The optical connector 78 can further include a sleeve 93 that is disposed forward of the alignment support housing 94. The biasing member 92 can seat against the alignment support housing 94 and the support member 84. In one example, the biasing member 92 can be configured as a coil spring, but can be configured as any suitable alternative biasing member as desired. The optical assembly 76 can further include an optical housing 96 that is configured to receive the support member 84, such that the support member 84 is fixed with respect to movement relative to the optical housing 96. The support member 84 can be mounted to the substrate 62. Because the support housing 24 is also mounted to the substrate 62, the substrate 62 can be referred to as a common substrate.

The latch member 88, and in particular the hook or barb 91, engages a complementary latch member 98 of the optical housing 96 to resist back-out of the support member 84 relative to the optical housing 96 in the rearward direction. In particular, the latch member 88 can engage the complementary latch member 98 when the support member 84 is inserted into the optical housing 96. The optical connector 78 can engage a stop structure 99 of the communication module 64 so as to prevent further movement of the optical connector 78 in the forward direction. Accordingly, as the support member 84 is inserted into the optical housing 96 the support member 94 compresses the biasing member 92, such that the biasing member 92 provides a forward biasing force against the optical connector 78. In one example, the latch member 88 can be configured as a first or top latch member 88a disposed inside the optical housing 96. In particular, the optical housing 96 can include a top wall 102 that covers the top latch member 88a. The top latch member 88a can thus be disposed between the underlying substrate 62 and the top wall 102 with respect to the transverse direction T. The optical housing 95 can defines a top aperture 103a that extends through the top wall 102 at a location in alignment with the top latch member 88a along the transverse direction T. In one example, a top complementary latch member 98a can partially define the top aperture 103a, or otherwise be disposed in or aligned with the top aperture 103a. Accordingly, a tool can be inserted into the top aperture 103a to disengage top latch member 88 from the top complementary latch member 98a when it is desired to remove the support member 84 from the optical housing 96.

The at least one latch member 88 of the support member 84 can further include a second or bottom latch member 88b opposite the top latch member 88a along the transverse direction T. The bottom latch member 88b can be sized and shaped substantially identical to the top latch member 88a. The bottom latch member 88b can be disposed inside the optical housing 96. The optical housing 96 can further include a bottom wall 100 opposite the top wall 102, such that the bottom wall 100 extends under the bottom latch member 88b. The optical housing 96 can define a bottom aperture 103b that extends through the bottom wall 100 in alignment with the bottom latch member 88 along the transverse direction T. A bottom complementary latch member 98b can partially define the bottom aperture 103b, or otherwise be disposed in or aligned with the bottom aperture 103b. Thus, a tool can be inserted into the bottom aperture 103b to disengage the bottom latch member 88b from the bottom complementary latch member 98b when it is desired to remove the support member 84 from the optical housing 96. The top and bottom apertures 103a and 103b can be sized less than either or each of the top and bottom latch members 88a and 88b, respectively, in respective planes that are oriented perpendicular to the transverse direction T. It should be appreciated that the communication module 64 can include a plurality of optical cable assemblies 76, wherein the support member 84 of each of the optical cable assemblies is supported by a respective optical housing 96.

It should be appreciated that the illustrations and descriptions of the examples shown in the figures are for exemplary purposes only and should not be construed as limiting the disclosure. One skilled in the art will appreciate that the present disclosure contemplates various embodiments. Terms such as above and below are relative to the orientation of the various elements described in the figures and need not describe the orientation of the element in a final product. Additionally, it should be understood that the concepts described above with the above-described embodiments may be employed alone or in combination with any of the other embodiments described above. It should further be appreciated that the various alternative embodiments described above with respect to one illustrated embodiment can apply to all embodiments as described herein, unless otherwise indicated.

1-84. (canceled)

85. A data communication system comprising:
a module housing having a first stop member;
an electrical cable connector supported by the module housing and biased by a spring in a mating direction;
a second stop member spaced from the first stop member along a longitudinal direction, wherein the mating direction is oriented along the longitudinal direction; and
a support housing disposed between the first and second stop members, wherein the support housing is configured to be mounted to a substrate,
wherein the module housing is movable with respect to the support housing and the substrate when the support housing is mounted to the substrate.

86. The data communication system of claim 85, wherein a length from the first stop member to the second stop member along the longitudinal direction is slightly greater than a length of a total length of the support housing along the longitudinal direction L, such that abutment between the support housing and the module housing limits movement of the module body with respect to the support housing.

87. The data communication system of claim 86, wherein the movement of the module body with respect to the support housing is in a lateral direction that is perpendicular to the longitudinal direction.

88. The data communication system of claim 87, wherein the movement of the module body with respect to the support housing is further in a transverse direction that is perpendicular to each of the longitudinal direction and the lateral direction.

89. The data communication system of claim 85, wherein the support member comprises a frame and an aperture that extends through the frame, wherein the module housing extends through the aperture.

90. The data communication system of claim 89, wherein the module housing is smaller than the aperture in a plane that is oriented perpendicular to the longitudinal direction, such that the module housing is movable with respect to the support housing inside the frame along at least one of a lateral direction that is oriented perpendicular to the longitudinal direction and a transverse direction that is oriented perpendicular to each of the longitudinal direction and the lateral direction.

91. The data communication system of claim 90, wherein the aperture has a substantially constant size along an entirety of its length through the support housing with respect to a plane perpendicular to the longitudinal direction.

92. The data communication system of claim 89, wherein the aperture is sized greater than the module housing in each of a lateral direction and a transverse direction that are perpendicular to each other and to the longitudinal direction.

93. The data communication system of claim 89, wherein the first stop member is disposed adjacent the frame in the mating direction, and the second stop member is disposed adjacent the frame a rearward opposite the mating direction.

94. The data communication system of claim 89, further comprising a retention member that includes the second stop member, wherein the retention member and the module housing cooperate so to capture the support housing while the module body is disposed in the aperture.

95. The data communication system of claim 85, wherein the cable connector defines a mating end that comprises a pin and a sleeve that surrounds the pin, wherein the pin is movable in a rearward direction opposite the mating direction against a spring force of the spring.

96. The data communication system of claim 95, wherein the pin extends from the sleeve in the mating direction, and is configured to mate with an electrical contact of a complementary cable connector

97. The data communication system of claim 96, wherein movement of the module housing causes corresponding movement of the mating end.

98. The data communication system of claim 85, wherein the electrical cable is a coaxial RF cable connector.

99. The data communication system of claim 85, wherein the module housing supports a plurality of electrical cable connectors, such that movement of the module housing in the lateral direction and in the transverse direction correspondingly moves each of the plurality of electrical cable connectors.

100. The data communication system of claim 85, wherein the electrical cable connector is snap-fit in the module housing.

101. The data communication system of claim 85, wherein the electrical cable connector is substantially fixed with respect to movement relative to the module housing in all directions perpendicular to the longitudinal direction.

102. The data communication system of claim 85, further comprising an optical cable assembly comprising:
an optical connector defining a mating end, wherein the optical connector supports at least one alignment member that extends out from the optical connector in a forward direction;
a support member that has a support body and at least one latch member that is cantilevered from the support body in the forward direction;
a plurality of optical fibers that extend through the support member and terminate at the optical connector, such that the optical fibers are in optical communication with the mating end;
a biasing member that extends from the optical connector to the support member so as to bias the optical connector in the forward direction, wherein the biasing member allows for resilient movement of the optical connector with respect to the support member along a direction offset from a longitudinal direction that includes the forward direction and a rearward direction opposite the forward direction.

103. The data communication system of claim 102, wherein the optical connector supports first and second alignment members that are spaced from each other along a transverse direction, and the latch member defines a hook in a plane that includes the longitudinal direction and a lateral direction that is perpendicular to each of the longitudinal direction and the transverse direction.

104. The data communication system of claim 103, wherein the mating end of the optical connector is disposed adjacent a mating end of the electrical cable connector.
